(19) United States
(12) Patent Application Publication
(10) Pub. No.: US 2025/0351472 A1
(43) Pub. Date: Nov. 13, 2025

(54) SYSTEM AND METHOD FOR DETERMINING SINGLE EVENT BREAKDOWN VOLTAGE FOR WIDE BANDGAP SEMICONDUCTOR POWER DEVICE

(71) Applicant: Vanderbilt University, Nashville, TN (US)

(72) Inventors: Steven Kosier, Nashville, TN (US); Arthur Witulski, Nashville, TN (US); Dennis Ball, Nashville, TN (US); Ronald Schrimpf, Nashville, TN (US); Kenneth Galloway, Nashville, TN (US)

(21) Appl. No.: 19/202,701

(22) Filed: May 8, 2025

Related U.S. Application Data
(60) Provisional application No. 63/644,187, filed on May 8, 2024.

(51) Int. Cl. H10D 62/10; H10D 62/60; H10D 62/832; H10D 62/85

(52) U.S. Cl. CPC H10D 62/105; H10D 62/60; H10D 62/8325; H10D 62/8503

(57) ABSTRACT

A system and method for determining a single event breakdown voltage for a wide bandgap semiconductor power device. The power device includes an epitaxial layer composed of a wide bandgap semiconductor material such as SiC having a critical energy density. A specific doping level is applied to the epitaxial layer based on a relationship between doping level and the critical energy density to produce a power device with a specific single event breakdown voltage.

### PRIORITY CLAIM

This application claims priority to U.S. Provisional Application No. 63/644,187, titled “Pre-Strike Analytical Model for SiC Power Device SEB from 1200V to 4500V” and filed on May 8, 2024, the contents of which are incorporated herein by reference in its entirety.

### STATEMENT REGARDING FEDERALLY SPONSORED RESEARCH OR DEVELOPMENT

This invention was made with government support under the NASA LuSTR Program, Grant No. 80NSSC21K 0766. The government has certain rights in the invention.

### FIELD OF THE TECHNOLOGY

The present technology relates to adjusting single event burnout voltage for high voltage devices built with wide-bandgap semiconductors, and specifically to controlling doping to adjust the energy stored in the depletion region of a silicon carbide device to increase the single event burnout voltage.

### BACKGROUND

Silicon based integrated circuits have been incorporated into power applications. However, silicon semiconductors have certain limitations. Recently, there have been explorations into power devices based on wide bandgap semiconductors such as Silicon Carbide (SiC), Gallium Oxide (Ga₂O₃), or Gallium Nitride (GaN). In particular, Silicon Carbide based power devices such as a field effect transistors (FET) or power diodes offer performance advantages over competing silicon based power devices due to the wide bandgap and other key material properties of 4H-SiC for commercial applications. Recently, SiC devices have seen broad and accelerating industry adoption in fields such as space applications, power grid applications, data centers, and power converters. Such devices offer system level performance advantages such as lower switching resistance in relation to power applications compared to conventional silicon based power devices.

However, deploying SiC power devices in heavy-ion radiation environments is not straightforward, as SiC power devices may suffer from catastrophic single-event burnout (SEB) well below their (terrestrial) rated breakdown voltage. Thus, applications in radiation environments such as space exploration or in a power grid may result in failure of critical power devices. Simple derating criteria useful for silicon power devices do not hold for SiC devices owing to the fundamentally different burnout mechanisms of the devices.

Circuit and system designers routinely de-rate power devices to build safety margins into their designs. Such derating always carries a performance penalty. FIG. 1 is a graph 10 that shows the performance penalty in an example currently used silicon carbide based power device. FIG. 1 shows a response in a plot 12 of current against voltage between the drain and source of a power device. As shown in FIG. 1, when a breakdown voltage, V_{BR} iS reached as represented by a line 14, current begins to flow through the device. Commercial SiC power devices have a rated voltage, V_{RATED}, represented by a mark 16 that is less than the breakdown voltage V_{BR} by some safety margin (typically 10-20%). As shown in FIG. 1, for SiC power devices, a single event burnout voltage, VSEB, represented by a mark 18, is the drain voltage at which single event burnout begins to occur. Reaching the single event burnout voltage causes current to flow through the device. This voltage is much less than V_{RATED} and thus compromises performance of the device. Furthermore, the ratio of VSEB to V_{RATED} Or V_{BR} is not constant; rather, the ratio decreases as V_{RATED} increases. Due to radiation exposure, SiC power devices are much more susceptible to single event burnout. Thus, the safe operation area (SOA) of such devices is much less when in a radiation exposed environment such as in outer space. The safe operation area in outer space shown as a dashed line 20, which is significantly less than the SOA on Earth as shown as a dashed line 22.

Thus, there is a need for a method to raise the single event breakdown voltage in a silicon carbide power device. There is a need for fabricating a silicon carbide device having a high single event breakdown voltage for high radiation environments. There is a need for a power device for radiation environments, or for other high-reliability environments, with a thinner epitaxial layer sufficient for a single event breakdown voltage but allowing better performance.

### SUMMARY

In one example, a device for conducting current is disclosed. The device includes an epitaxial layer composed of a wide bandgap semiconductor material having a critical energy density with a specific doping level. The specific doping level is determined to provide a specific single event breakdown voltage corresponding to the critical energy density for the device. A drain layer is in contact with the epitaxial layer.

In another disclosed implementation of the example device, the wide bandgap semiconductor material is silicon carbide (SiC). In another disclosed implementation, the wide bandgap semiconductor material is gallium nitride (GaN), gallium oxide (Ga₂O₃), aluminum nitride (AlN), cubic boron-nitride (c-BN), or diamond. In another disclosed implementation, the device is a diode, wherein the drain layer is the cathode and an anode is defined in the epitaxial layer. In another disclosed implementation, the example device is a field effect transistor. The device further includes a source contact; a gate; and a source in proximity to the gate and coupled to the source contact. The source is coupled to the epitaxial layer and the current flow between the source and the drain is controlled by a gate voltage. In another disclosed implementation, the doping level is approximately between 1e14 cm⁻³ to 5e16 cm⁻³ corresponding to a single event breakdown voltage approximately between 2400 and 300 volts. In another disclosed implementation, a maximum thickness of the epitaxial layer is selected based on a thickness of a depletion region in the epitaxial layer at the single event breakdown voltage. In another disclosed implementation, the doping level, NEPI, is determined by solving the equation:

$${V}_{SEB , sat} = {( \frac{2 * {U}_{SEB , sat}}{\sqrt{2 q {ε}_{o} {ε}_{SiC}}} )}^{\frac{2}{3}} {N}_{EPI}^{- \frac{1}{3}}$$

where U_{SEB,sat} is the critical energy stored in the epitaxial layer at the single event breakdown voltage, V_{SEB,sat} is the single event breakdown voltage, q is a magnitude of electronic charge, & is a permittivity of free space, and ε_{SiC} is a relative permittivity of the wide bandgap semiconductor.

Another disclosed example is a method of fabricating a wide bandgap semiconductor power device having a single event breakdown voltage. A critical energy density value of a wide bandgap semiconductor material is determined. A doping level of an epitaxial layer for a desired single event breakdown voltage corresponding to the critical energy density is determined. A substrate is doped to form a drain layer. An epitaxial layer of the wide bandgap semiconductor material is formed on the drain layer. The wide bandgap semiconductor material is doped at the determined doping level.

In another disclosed implementation of the example method, the wide bandgap semiconductor material is silicon carbide (SiC). In another disclosed implementation, the wide bandgap semiconductor material is gallium nitride (GaN), gallium oxide (Ga₂O₃), aluminum nitride (AlN), cubic boron-nitride (c-BN), or diamond. In another disclosed implementation, the device is a diode, the drain layer is the cathode and an anode is defined in the epitaxial layer. In another disclosed implementation, the device is a field effect transistor. The example method further includes growing a source contact on the epitaxial layer opposite the drain layer. The example method includes doping two source regions under the source contact in the epitaxial layer; and growing a gate between the source regions. In another disclosed implementation, the doping level is approximately between 1e14 cm⁻³ to 5e16 cm⁻³ corresponding to a single event breakdown voltage approximately between 2400 and 300 volts. In another disclosed implementation, a maximum thickness of the epitaxial layer is selected based on a thickness of a depletion region in the epitaxial layer at the single event breakdown voltage. In another disclosed implementation, the doping level, NEPI, is determined by solving the equation:

$${V}_{SEB , sat} = {( \frac{2 * {U}_{SEB , sat}}{\sqrt{2 q {ε}_{o} {ε}_{SiC}}} )}^{\frac{2}{3}} {N}_{EPI}^{- \frac{1}{3}}$$

where U_{SEB,sat} is a critical energy stored in the epitaxial layer when the single event breakdown voltage occurs, V_{SEB,sat} is the single event breakdown voltage, q is a magnitude of electronic charge, so is a permittivity of free space, and ε_{SiC} is a relative permittivity of the wide bandgap semiconductor.

Another disclosed example is a method to determine a single event breakdown voltage for a power device including an epitaxial layer composed of a wide bandgap semiconductor material coupled to a drain. A critical energy density value of the wide bandgap semiconductor material is determined. A doping level of the epitaxial layer is determined. The single event breakdown voltage of the power device based on the doping level of the epitaxial layer is determined.

In another disclosed implementation, the single event breakdown voltage (V_{SEB,sat}) is determined via:

$${V}_{SEB , sat} = {( \frac{2 * {U}_{SEB , sat}}{\sqrt{2 q {ε}_{o} {ε}_{SiC}}} )}^{\frac{2}{3}} {N}_{EPI}^{- \frac{1}{3}}$$

where U_{SEB,sat} is a critical energy stored in a critical energy stored in the epitaxial layer when the single event breakdown voltage occurs, q is the magnitude of electronic charge, ε₀ is the permittivity of free space, ε_{SiC} is the relative permittivity of the wide bandgap semiconductor, and N_{EPI} is the doping level. In another disclosed implementation, the device is one of a diode or a transistor. In another disclosed implementation, the wide bandgap semiconductor material is silicon carbide (SiC).

The above summary is not intended to represent each embodiment or every aspect of the present disclosure. Rather, the foregoing summary merely provides an example of some of the novel aspects and features set forth herein. The above features and advantages, and other features and advantages of the present disclosure will be readily apparent from the following detailed description of representative embodiments and modes for carrying out the present invention when taken in connection with the accompanying drawings and the appended claims.

### BRIEF DESCRIPTION OF THE DRAWINGS

The present technology is illustrated by way of example, and not by way of limitation, in the figures of the accompanying drawings, in which like reference numerals refer to similar elements including:

FIG. 1 is a graph of single event breakdown voltages in a known prior art Silicon Carbide (SiC) power device;

FIG. 2 is a cross-section view of a SiC power device and corresponding graphs showing operational parameters;

FIG. 3 is an equivalent lumped circuit model of the example SiC power device in FIG. 2;

FIG. 4 is a graph showing test results for SiC power devices in relation to single event breakdown voltage in high linear energy transfer radiation environments;

FIG. 5 is a table showing parameters for the tested SiC power devices in FIG. 4;

FIG. 6 is a graph showing test results for SiC power devices in FIG. 4 in relation to single event breakdown voltage in low linear energy transfer radiation environments;

FIG. 7 is a graph showing average single event breakdown voltage versus epi doping of test devices;

FIG. 8 is a graph that plots power law dependencies on epi doping levels of the test devices;

FIG. 9A is a table of example parameters for designing wide bandgap semiconductor devices;

FIG. 9B is a graph that shows the calculation of epi doping levels to achieve desired single event voltages for designing wide bandgap semiconductor devices;

FIG. 10 is a cross-section view of an example Gallium Nitride power device;

FIG. 11 is a cross section of an example Gallium Oxide diode;

FIG. 12 is a graph of the single event breakdown voltage of the example Gallium Oxide diode in FIG. 11; and

FIG. 13 is a flow diagram of a process to determine the single event breakdown voltage of a wide bandgap semiconductor power device.

### DETAILED DESCRIPTION

Before the present technology is described in further detail, it is to be understood that the technology is not limited to the particular examples described herein, which may vary. It is also to be understood that the terminology used in this disclosure is for the purpose of describing only the particular examples discussed herein, and is not intended to be limiting.

The following description is provided in relation to various examples which may share one or more common characteristics and/or features. It is to be understood that one or more features of any one example may be combinable with one or more features of another example or other examples. In addition, any single feature or combination of features in any of the examples may constitute a further example.

The disclosed system and method are based on the value of the single event breakdown voltage (V_{SEB}) being dependent on the stored pre-strike energy of wide bandgap semiconductor devices. For example, the SEB voltage of a SiC power device for high linear energy transfer (LET) from radiation exposure may be determined by calculating pre-strike energy stored in the drain-body depletion region of a drain to body epitaxial layer of the device. The pre-strike energy is related to the critical energy density of the SiC material that in turn relates to the SEB voltage. This insight allows SiC power devices to be designed for targeted SEB voltage values. An example power device may be designed to control the doping of the drain-body depletion region to achieve a desired SEB voltage. The example design may be based on a physical model for SiC power MOSFET burnout by calculating the pre-strike critical energy density stored in the reverse-biased drain-body depletion capacitance. An example critical energy density of 310 μJ/cm² is determined for the SiC drain-body. The model allows determination of V_{SEB} for a wide range of epitaxial doping and device voltage ratings for a wide bandgap semiconductor material device. For example, SiC power MOSFETs with 900V V_{SEB} are demonstrated (average over six devices was 888 V), with an epitaxial doping of 2×10¹⁵ cm⁻³ (2E15 cm⁻³) determined from the model. The relative independence of V_{SEB} to epitaxial thickness allows the thickness to be minimized thus resulting in better performance. Thus, an example radiation hardened SiC power MOSFET may be produced with a high single event breakdown voltage by lighter epitaxial doping but with a thinner epitaxial drain-body, resulting in lower on-resistance for the example device.

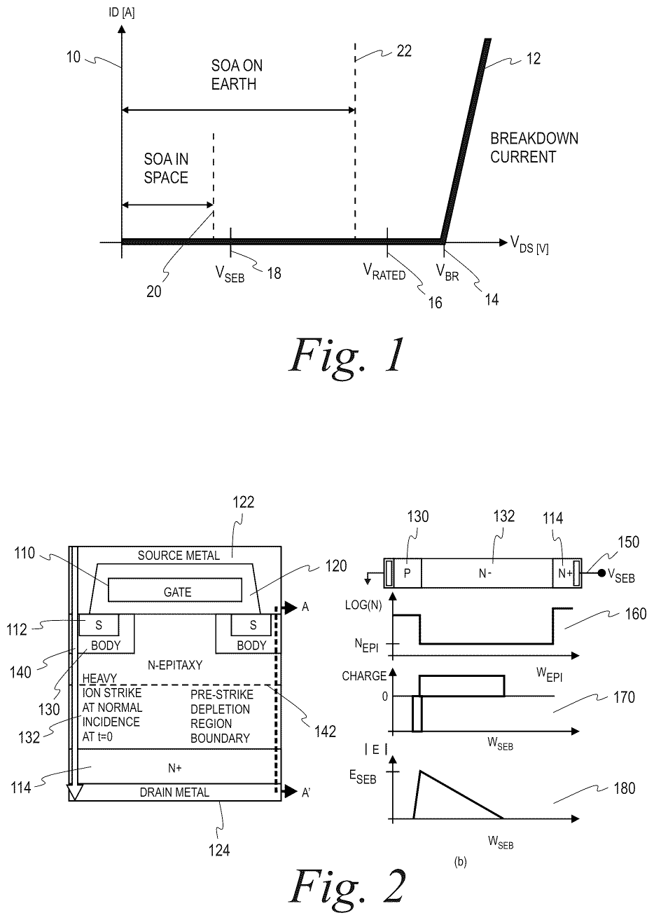

FIG. 2 is a cross-section of an example SiC power device 100. In this example, the SiC power device 100 is an example SiC field effect transistor. The device 100 includes a gate 110, a source 112, and a drain 114. The gate 110 is supported by an insulation layer 120. The gate 110 is connected to an electrical contact (not shown) to control current flow between the source 112 and the drain 114. A source contact 122 allows electrical contact to be made to the source 112. A drain contact 124 allows electrical contact to be made to the drain 114. The source 112 is formed on a p-doped body region 130. An n-doped epitaxial drain body layer 132 has a certain depletion region based on voltage applied.

An arrow 140 represents the ion track of ion radiation on the device 100. Single event breakdown occurs when the ion track represented by the arrow 140 extends through the device. Thus, ion radiation may cause a single event breakdown at a certain SEB voltage for the device that is less than the rated breakdown voltage. A depletion width at the single event breakdown voltage is represented by a dashed line 142. As will be explained below, the depletion width is less than the overall thickness of the drain body layer 132. Thus, with the lower SEB compared with the breakdown voltage as a design parameter for SOA, the thickness of the drain body layer 132 may be minimized to at least the depletion width and may be even thinner.

An inset 150 shows a cross section of the device 100 along the lines A-A′ that may be considered as a drain-body diode. As may be seen in the inset 150, an N-region of the drain body layer 132 is located between the p-doped body region 130 of the source 112 and the N+ doped region of the drain 114. As will be detailed, the principles herein for designing single event breakout voltages may be applied to either diodes or FETs constructed of wide bandgap semiconductor materials. A doping level graph 160 shows the doping level of the regions 130, 132 and 114. A space charge graph 170 shows that charge is stored in the drain body layer 132 in the region defined by the depletion width, W. An electric field graph 180 shows that electric field is higher in the depletion region that is in proximity to the body region 130 and linearly declines to the edge of the depletion region represented by the dashed line 142. The electric field thus does not extend over the entire epitaxial drain body layer 132.

In this example, the single event breakdown voltage of the device 100 may be controlled by setting the doping level of the epitaxial drain body layer 132. As will be explained, the single event breakdown voltage is a function of a specific pre-strike energy stored by the material of the epitaxial drain body layer 132 and the doping level of the layer 132. This energy is related to the critical energy density of the material of the epitaxial drain body layer 132. The doping level of the epitaxial drain body layer 132 thus may be controlled to control the single event breakdown voltage of the device 100. Alternatively, the pre-strike energy may be distributed between the epitaxial layer and another layer or layers of other devices. However, the principles herein apply to such devices as the pre-strike energy would include the portion distributed to other layers in order to calculated the doping of the epitaxial layer to achieve a desired single event breakdown voltage.

FIG. 3 is a lumped RC circuit model 300 of the example SiC power device 100. The physical mechanisms occurring in the device post-strike are extraordinarily complex and require detailed simulations and calculations. Accurate models for the extreme conditions (short time, high carrier concentration, high temperature, high field) present during an SEB event are difficult to obtain. However, a lumped RC model such as the circuit model 300 can provide physical insight to burnout mechanisms post-strike.

In the lumped RC circuit model 300, resistors are the dissipative element. Thus, the circuit model 300 includes a resistor 310 that represents the resistance of the source contact 122 and a resistor 312 that represents the resistance of the drain contact 124 in FIG. 2. The resistors 310 and 312 represent the resistance from the bond pads through the metallization to the precise physical location of the ion strike. This resistance will be variable depending on the location of the strike.

A resistor 314 models the targeted contact closest to the centerline of the ion strike. Thus, the resistor 314 models a physically small region (μm²). As such, the resistance of the resistor 314 is on the order of ohms and has a high power density at the single event breakdown voltage. A resistor 316 models the common, backside contact of the drain body layer 132, which is a physically large region (mm²). As such, the resistance value of the resistor 314 is small (mΩ) and has low power density at the single event breakdown voltage.

A capacitor 320 represents the depletion energy that may be stored in the drain body layer 132. The resistance of the undepleted, cylindrical epitaxial region of the layer 132 is represented by a resistor 322. A variable resistor 324 represents the effects of radiation. The resistance of the resistor 324 be large or small depending on LET and the depletion width, W_{EPI}, and can have large or small power density at the single event breakdown voltage depending on the evolution of the electron-hole plasma post-strike.

Thus, when the device 100 is exposed to radiation, the variable resistor 324 is coupled between the voltage contacts and shorts out the resistor 322, causing current flow at the single event breakdown voltage. An external series resistor is not effective at preventing burnout in SiC devices, unlike with Si power MOSFETs. An external resistor would appear to the right of the arcs, which represent parasitic impedance. Such external resistors are electrically distant (large RC time constant compared to the SEB event) and cannot respond quickly enough to influence or prevent SEB in SiC devices. In contrast, if the ion track did not fully traverse the epitaxial drain body layer 132, then the variable resistor 324 would not completely short out the resistor 322, leaving a (˜1000 times larger than the resistance of the resistor 324) term in series with the resistor 324 in the circuit and interior to the structure. This would serve to limit the current, i(t), and prevent SEB, consistent with experimental observation.

Since the single event breakdown voltage that causes saturation can be well-modeled by energy storage pre-strike, the stored energy must be released into the structure where it causes single event breakdown. M ore precisely, upon release from the passing heavy ions, the stored energy converts into power dissipation in the structure, ultimately leading to SEB when the device is biased at or above the single event breakdown voltage (V_{SEB}). Guided by the lumped RC circuit model 300, SEB occurs when a critical volume power density is exceeded in the structure, causing localized damage. Such models generally fall into the “thermal spike effects” category and proceed at ps timescales. This appears to be a dominant mechanism for the low linear energy transfer (LET) case.

The example principles of determination of single event breakdown based on high linear energy transfer (LET) representing exposure to ion radiation was tested. In the testing, five different SiC power device designs for power devices such as diodes and FETs were considered. For each test device 1-5, between three and six devices were tested, and the average value of V_{SEB} was reported. The V_{SEB} data for each device/LET combination typically fell within +/−25V. Devices 1, 3 and 4 were commercial devices with specified rated breakdown voltages. Devices 2 and 5 were experimental devices with different epitaxial layer thicknesses. The experimental test devices differed from the commercial test devices primarily in their epitaxial layer (epi) parameters of epi doping and epi thickness. The process flow of the experimental test devices was identical to the commercial text devices. Hence, differences observed between devices are entirely attributable to the intentional epitaxial layer experiments that were performed, not due to other sources of variation. The test devices were made of 4H-SiC and packaged in open-cavity standard TO-247 packages. The devices were tested with a fixed drain bias, and with gate and source terminals grounded. Many different heavy ions at various LET values were tested. All the devices were tested at the K 500 accelerator facility at Texas A & M University Cyclotron Institute. The devices were irradiated with a fluence of 10⁶ ions/cm² at each bias step.

Heavy ions with various LET values were selected for the tests. All LET values are reported for SiC. The heavy ions used for irradiation of the SiC power diodes and MOSFETS tested were 15 M eV/u neon (Ne), argon (Ar), krypton (Kr), silver (Ag) and Praseodymium (Pr). For the analytical modeling, focus was on very high LET data at normal incidence, with the ¹⁴¹Pr isotope. In this example, the high LET was approximately 64 MeV/(mg/cm²) for the Praseodymium isotope, and the resulting range of the Praseodymium isotope heavy ions in the SiC material was approximately 80 μm, after a 3 cm air gap between the ion source and the target SiC devices. All the heavy ions used for these tests had a range that fully traversed the epitaxial region of the test devices. Heavy ions that do not fully traverse the epitaxial region do not cause burnout in SiC power devices.

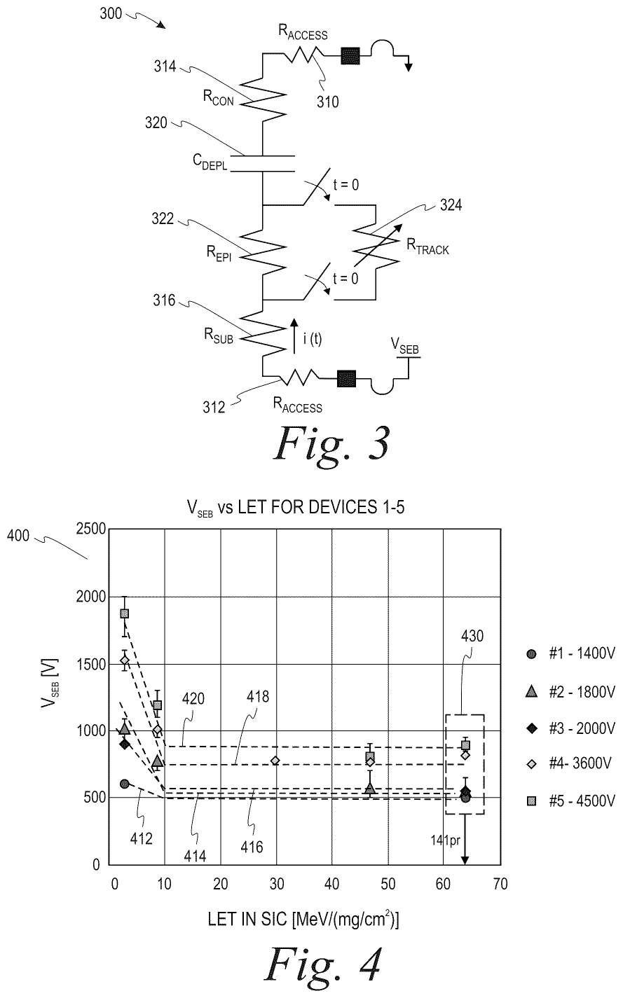

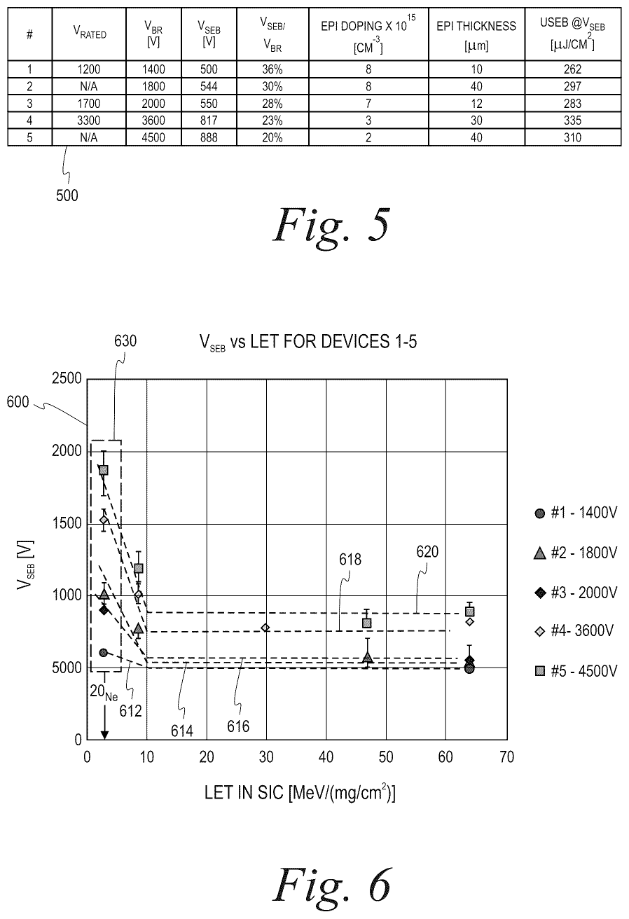

FIG. 4 shows the average single event break down voltages plotted against the LET for each of the test devices. Thus, data point plots 412, 414, 416, 418, and 420 represent each of the five test device designs. The data points are numbered with reference to a table 500 in FIG. 5 that lists the parameters of the test devices. Data from both MOSFET and diode devices according to the parameters in the table 500 were reported from the testing data plotted in FIG. 4. A worst case single event voltage was determined as shown in the dashed box 430. Based on known data, the worst-case V_{SEB} for the SiC test devices is approximately constant for a LET>10 M eV/(mg/cm²) and is generally the same for both SiC MOSFETs and diodes. Thus, the single event breakdown voltage V_{SEB} has a linear relation to LET for low LET below 10 MeV/(mg/cm²). As shown in FIG. 4, this holds true for the data from the test devices.

FIG. 5 is a table 500 that provides structural and experimental details for each test device. Structural parameters of diodes and MOSFETs in the testing, along with important voltages and depletion energy at V_{SEB} are shown in the rows for each of the test devices. These include the ratio of V_{SEB} to V_{BR}, the doping of the epitaxial layer, the thickness of the epitaxial layer, and the total energy at the V_{SEB}. Average V_{SEB} for ¹⁴¹Pr irradiation is reported from the testing in the table 500.

As shown in the table 500, the commercially available test devices varied in rated breakdown voltage (V_{RATED}) from 1.2 kV to 3.3 kV, and the experimental test devices have breakdown voltages (V_{BR}) from ˜1.4 kV to ˜4.5 kV. Since the experimental test devices did not have a definite voltage rating, and since the breakdown voltage can be either B_{VDSS} for MOSFETs or B_{VAK} for diodes, V_{BR} was reported instead and understood to mean average reverse blocking voltage for the power device in the off-state.

As shown in table 500, experimental test devices 2 and 5 differ in epitaxial doping but are otherwise identical. Devices 1 and 2 have the same epitaxial doping but very different epitaxial layer thicknesses. Devices 3 and 4 provide additional data points for the model. Hence, the testing was based on a consistent experimental data set in which epi doping, N_{EPI} [cm⁻³] and epi thickness are independently and individually varied.

Based on the results in table 500, the V_{SEB}/V_{BR} ratio decreases as V_{BR} increases. The experimental test devices 2 and 5 differed in epi doping but are otherwise identical. Their (identical) epi thickness is 40 μm, which is appropriate for a 4500 V V_{BR} commercial device. Based on electrical breakdown, the epi thickness is typically chosen so that the depletion region extends through the entire epi layer at V_{BR}. V_{BR} follows epi doping, as expected. The notable result, however, is that V_{SEB} is very different for devices 2 and 5, 544 V vs 888 V based on epi doping.

Devices 1 and 2 have the same epi doping but very different epi thicknesses, 10 μm vs. 40 μm. As can be seen, the V_{BR} of devices 1 and 2 is similar, as is the V_{SEB}, emphasizing that epi thickness is not a primary determinant of V_{SEB}. Devices 3 and 4 are commercial devices that have epi doping and thickness that lie between the extremes of devices 1, 2, and 5, and were chosen for the commercial voltage rating of the respective devices.

The final column of the table 500 introduces the energy stored in the depletion region at V_{SEB}, U_{SEB}, with units of μJ/cm², derived as explained herein. As can be seen in the table 500, U_{SEB} at V_{SEB}, called U_{SEB,sat}, is approximately constant for devices 1 through 5, although the epi thickness and doping for devices 1 through 5 vary significantly. The term U_{SEB,sat} is chosen because V_{SEB} saturates for LET>10 M eV/(mg/cm²) as shown in FIG. 4. Thus, V_{SEB} Sat is the constant single event breakdown voltage for a device at high LET values above 10 M eV/(mg/cm²)

Additional testing was performed on the test devices 1-5 for low LET (LET<10 MeV/(mg/cm²)), These tests showed that V_{SEB} increases with decreasing LET for all devices. FIG. 6 is a graph 600 of V_{SEB} vs low LET, with emphasis on data resulting from ²⁰Ne isotope radiation directed at the test devices. FIG. 6 shows the average single event break down voltages plotted against the low LET for each of the test devices. Thus, data point plots 612, 614, 616, 618, and 620 represent each of the five test devices.

In terms of the model, Rtrack in the low LET regime is larger than for high LET, since there is less charge deposition from the radiation along the ion track at lower LET. As such total resistance, Rtotal=Rcon+Rtrack+Rsub (resistors 314, 322, and 316 in FIG. 3) limits the terminal current, i(t) compared to the high LET case. With i(t) limited, more energy storage USEB can be tolerated before burnout, and hence, a higher VSEB is observed for all devices than in the high LET (LET>10 M eV/(mg/cm²) case.

To illustrate this concept more precisely, comparing devices 1 and 2 for ²⁰Ne irradiation, LET=2.8 M eV/(mg/cm²), with a range in SiC of 188 μm, is useful. Devices 1 and 2 have similar VSEB,sat since they have the same epi doping. However, device 2 had 4× larger W_{EPI} than that of device 1, and as such, has a 4× larger Rtrack than device 2.

Accordingly, device 2 has 70% higher V_{SEB} than device 1. In this case, the higher Rtrack of device 2 led to significantly higher observed V_{SEB} than device 1 for low LET in otherwise nearly identical devices, as the lumped model would suggest.

However, it must be noted that devices 1 and 3 have similar structural parameters, but device 3 shows a larger increase in V_{SEB} than device 1 at low LET. This burnout mechanism is where damage occurs when power density in the ion track exceeds a threshold value, PP. Such a model predicts that V_{SEB}∝(PP/LET)1/2, somewhat consistent with the low LET data, in that a lower LET gives higher V_{SEB} as shown in the dashed box 630 in FIG. 6 This model is not applicable to the high LET data as shown in FIG. 4, as it predicts an ever-lower V_{SEB} With increasing LET, and does not explain why V_{SEB,sat} would depend on N_{EPI} as described by Equation (4).

A few simplifying assumptions were made for the testing: (a) the epi doping Nₑₚᵢ<<p-type body doping (one-sided step junction). For typical devices, this ratio is 100:1 or more. (b) V_{SEB}>>V_{bi} (built-in junction potential). For SiC, V_{bi} is about 2.5 V, at least 100 times lower than the smallest V_{SEB} considered. (c) the depletion width W_{EPI}>>Body junction depth. A typical junction depth for SiC power devices is less than 1 μm, more than 10 times smaller than the thinnest epi layer in the test devices. With these assumptions, the depletion width at V_{SEB}, W_{SEB} [μm], may be written as:

$${W}_{SEB} \approx \sqrt{\frac{2 {ε}_{o} {ε}_{SiC} {V}_{SEB}}{q {N}_{EPI}}} , \qquad ( 1 )$$

where the constants q is the magnitude of electronic charge (1.6×10⁻¹⁹ C), ε₀ is the permittivity of free space (8.85×10⁻¹⁴ F/cm), and ε_{SiC} is the relative permittivity of the wide bandgap semiconductor material, which is SiC (9.7) in this example. The relative permittivity of other wide bandgap semiconductors will differ such as that of GalliumNitride ε_{GaN}. W_{SEB} is less than the epi layer thickness in all the test devices as reflected by the dashed line 142 in FIG. 2. The charge in the depletion region, Q_{depl}, [C/cm²] at V_{SEB} is

$$\vert {Q}_{depl} \vert = {qN}_{EPi} {W}_{SEB} = q {N}_{Epi} \sqrt{\frac{2 {ε}_{o} {ε}_{SiC} {V}_{SEB}}{q {N}_{EPI}}} = \sqrt{2 q {ε}_{o} {ε}_{SiC} {N}_{EPI} {V}_{SEB}} \qquad ( 2 )$$

The energy stored in this depletion region capacitance at V_{SEB} is U_{SEB}, [J/cm²] is therefore expressed as:

$${U}_{SEB} = \frac{1}{2} {Q}_{depl} {V}_{SEB} = \frac{1}{2} \sqrt{2 q {ε}_{o} {ε}_{SiC} {N}_{EPI} {V}_{SEB}} {V}_{SEB} = \frac{1}{2} \sqrt{2 q {ε}_{o} {ε}_{SiC} {N}_{EPI}} {V}_{SEB}^{\frac{3}{2}} \qquad ( 3 )$$

This formulation expresses U_{SEB} solely in terms of V_{SEB} and N_{EPI}, with no dependence on epi thickness or any other parameters. U_{SEB} carries units of J/cm² and so is independent of the device area.

As mentioned above, devices 2 and 5 are particularly interesting, as they are identical, except for epi doping. Devices 2 and 5 exhibit very different V_{SEB} but they have nearly identical U_{SEB}. From these two devices the calculated critical energy density for SiC, U_{SEB,crit}=310 μJ/cm². From the data shown in the table 500, it appears that U_{SEB,crit} is approximately constant across the devices tested. This quantity is interpreted as the minimum areal energy density required for SEB to occur in 4H SiC devices.

Furthermore, devices 1 and 2 have the same epi doping, very different epi thickness, but almost identical V_{SEB}. This demonstrates that epi thickness is not the primary factor driving V_{SEB}, but rather epi doping, in further support of the model.

Since U_{SEB,sat} is approximately constant, solving for V_{SEB,sat}:

$${V}_{SEB , sat} = {( \frac{2 * {U}_{SEB , sat}}{\sqrt{2 q {ε}_{o} {ε}_{SiC}}} )}^{\frac{2}{3}} {N}_{EPI}^{- \frac{1}{3}} \qquad ( 4 )$$

allows the V_{SEB} of any vertical SiC power device to be expressed solely in terms of the epi doping. Thus Equation 4 shows that V_{SEB,sat} is expressed only in terms of epi doping, N_{EPI} rather than the length of the epi region W_{EPI}.

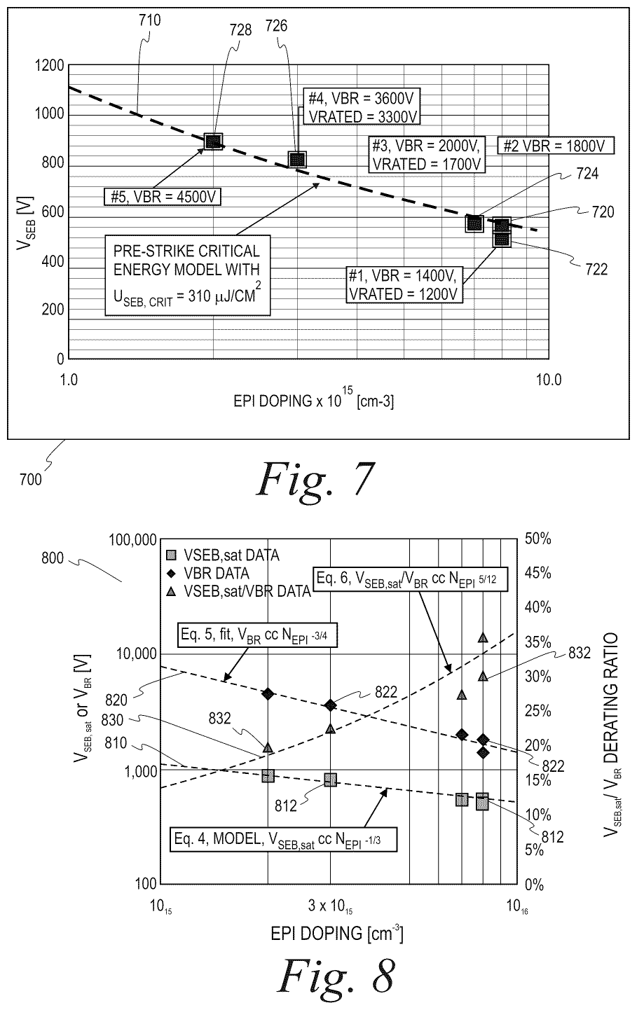

The model was compared to experimental data. FIG. 7 is a graph 700 that shows the average constant single event breakdown voltage, V_{SEB,sat} versus epi doping for the test SiC power MOSFETs compared to the results from calculating Equation 4 shown in the dashed line 610. Boxes 720, 722, 724, 726, and 728 show the average single event voltage breakdown versus epi doping for respective test devices 1-5. As may be seen in the graph 700, good agreement is seen for all devices considered.

The breakdown voltage data can be fit to a good (R²>0.097) approximation by the expression:

$${V}_{BR} \approx 1.4 \times {10}^{15} \times {N}_{EPI}^{- 3 / 4} \qquad ( 5 )$$

The fitting process was conducted using Microsoft Excel, which provided a nonlinear regression analysis directly applied to the data. Combining Equations 4 and 5 allows an empirical expression of the V_{SEB,sat}/V_{BR} derating ratio to be expressed as:

$${V}_{SEB , sat} / {V}_{BR} \approx 7.9 \times {10}^{- 8} \times {N}_{EPI}^{5 / 12} \qquad ( 6 )$$

FIG. 8 is a graph 800 that plots the results of Equations 4, 5, and 6 together, along with the data from the testing in table 500 so the different power-law dependencies on N_{EPI} can be readily seen. The horizontal axis of the graph 800 is the epi doping in cm⁻³ and vertical axis is breakdown voltage, single event breakdown voltages, and the derating ratio. The graph 800 includes a dashed line 810 that represents the single event breakdown voltage results of the model from Equation 4 based on epi doping level. Boxes 812 represent the single event breakdown voltage data from the test devices. A dashed line 820 represents the breakdown voltage results of Equation 5. Diamonds 822 represent the breakdown voltage data from the test devices. A dashed line 830 represents the derating ratio results of Equation 6. Triangles 832 represent the derating ratio data from the test devices.

Notably, V_{BR} increases faster than V_{SEB,sat} as N_{EPI} decreases. This is why the “derating factor,” V_{SEB,sat}/V_{BR}, also decreases as N_{EPI} decreases. Thus, obtaining higher voltage SiC devices necessitates moving to lower doping, N_{EPI}. Improvement in breakdown voltage, V_{BR} With decreased doping is expected, as described by Equation 5. The V_{SEB,sat} performance correspondingly improves, but V_{SEB,sat} does not increase nearly as much as V_{BR} with decreasing N_{EPI}. Hence, more derating is required for higher voltage SiC devices.

The above principles may be incorporated into different applications. One application is the design of efficient wide bandgap semiconductor based power devices such as diodes and transistors. Given the relative independence of V_{SEB,sat} and epi thickness, and knowing that V_{SEB,sat}<V_{BR} as per Equation 6, SiC devices designed for a particular V_{SEB,sat} may have thinner epitaxial layers than commercial designs for a targeted V_{BR} would indicate. For example, the area in the epitaxial region below the dashed line 142 in FIG. 2 (the undepleted epi region below WEB) is “wasted” in that it contributes to series resistance and can give a higher breakdown voltage V_{BR} but does not improve the single event breakdown voltage, V_{SEB}. Therefore, the optimum epitaxial thickness, W_{EPI} for a single event breakdown is thinner than that of commercial SiC power devices.

Such a design would begin with the desired wide bandgap semiconductor material. The energy stored by the wide bandgap semiconductor material is determined. The desired single event breakdown voltage may then be selected. Based on solving Equation 4 by inputting the desired single event breakdown voltage and energy stored by the epitaxial layer semiconductor material, the required output doping level is calculated. The process to fabricate the device thus will dope the epitaxial layer at the determined doping level to achieve the selected single event breakdown voltage.

One example of a power device is a radiation hardened SiC power MOSFET having lighter epi doping (e.g., of 2×10¹⁵ cm⁻³) resulting in a higher V_{SEB} of 900 V. As explained above, the epi doping level is determined by using a stored energy of 310 μJ/cm² and the desired single event voltage breakdown of 900 V. The epitaxial layer in this example MOSFET has a thickness of 40 μm. This value is approximately two times greater than the depletion region length at V_{SEB}. This means that even thinner epitaxial layers of 20 μm could be used because the energy storage is in the PN junction, near the surface of the epitaxial layer. Thus, the epitaxial layer may be made even thinner without substantially affecting the V_{SEB}. Other power devices such as SiC FETs and diodes may be designed with a single event voltage breakdown voltage of even higher V_{SEB} as high as 1500 V or 2000 V with corresponding doping of 4×10¹⁴ cm⁻³ to 2×10¹⁴ cm⁻³ of the epitaxial layer.

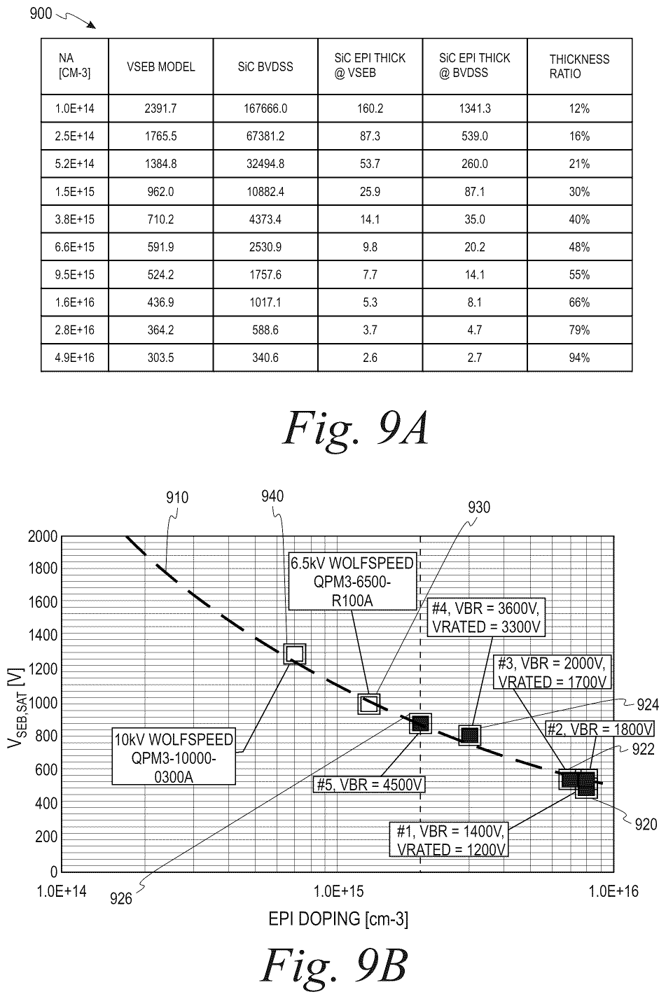

The maximum required thickness of the epitaxial layer of 40 μm in this example allows doping to range from approximately 1e14 cm⁻³ to 5e16 cm⁻³ for the corresponding single event breakdown voltage range of approximately 2400 to 300 volts respectively. As noted above, for any desired single event breakdown voltage the epitaxial layer could be thinner than the maximum thickness for even less turn on resistance. The depletion region varies with doping and thus the depletion region varies from 160.2 μm at 1e14 cm⁻³ doping to 2.6 μm at 4.9E16 cm⁻³ doping. The key point is that the doping level sets the avalanche breakdown voltage, and this sets the epitaxial layer thickness. As explained above, the doping of the epitaxial layer also sets the SEB voltage. The SEB voltage is less than the avalanche breakdown voltage, VBR. Since VSEB<VBR, the width of the epitaxial layer (WSEB) is less than the width for the breakdown voltage (WBR), and so the required epitaxial thickness is correspondingly smaller. FIG. 9A is a table 900 that shows device parameters according to a range of doping levels. The table 900 shows the corresponding single event breakdown voltage, the avalanche breakdown voltage (BV DSS), the epi layer thickness at the VSEB, the epi layer thickness at the BV DSS, and the thickness ratio between the thicknesses at VSEB and BVDSS.

The lower the thickness ratio, the more substantial the advantage of the proposed approach. For example, the design with NA=5.2e14 cm⁻³ doping has a thickness ratio of 21%, meaning a device designed with this approach will have an on-resistance that is only 21% of what a corresponding commercial device would have, a nearly 5× reduction.

FIG. 9B is a graph that plots single event voltage breakdown voltage and doping levels for design of high single event breakdown voltage devices. A plot 910 is derived from solving Equation 5. Various test data points for the test devices are shown on the plot 910. Thus, box 920 represents the results from test device 1, box 922 represents the results from test device 2, box 924 represents the results from test device 3, and box 926 represents the results from test devices 4 and 5. Thus, a device similar to a Wolfspeed 6.5 kV breakdown voltage device with a single event voltage breakdown of 1000 V may be designed with a specific doping level as shown in the box 930. A device similar to a Wolfspeed 10 kV breakdown voltage device with a single event voltage breakdown of 1200 V may be designed with a specific doping level as shown in the box 940.

Other power devices based on other wide bandgap semiconductor materials may also be designed according to the above principles. For example devices based on wide bandgap semiconductors other than diodes and transistors may incorporate the above principles. A similar analysis framework may be valid for other wide bandgap semiconductor material systems such as GaN, Ga₂O₃, aluminum nitride (AlN), cubic boron-nitride (c-BN), diamond and the like using the specific value for U_{SEB,sat} for the material. For example, V_{SEB}<<V_{BR} for GaN devices, especially for larger V_{BR} in the 600 V range, and external series resistors cannot prevent burnout. Another application may be for Ga₂O₃ vertical power devices where V_{SEB}<<V_{BR}.

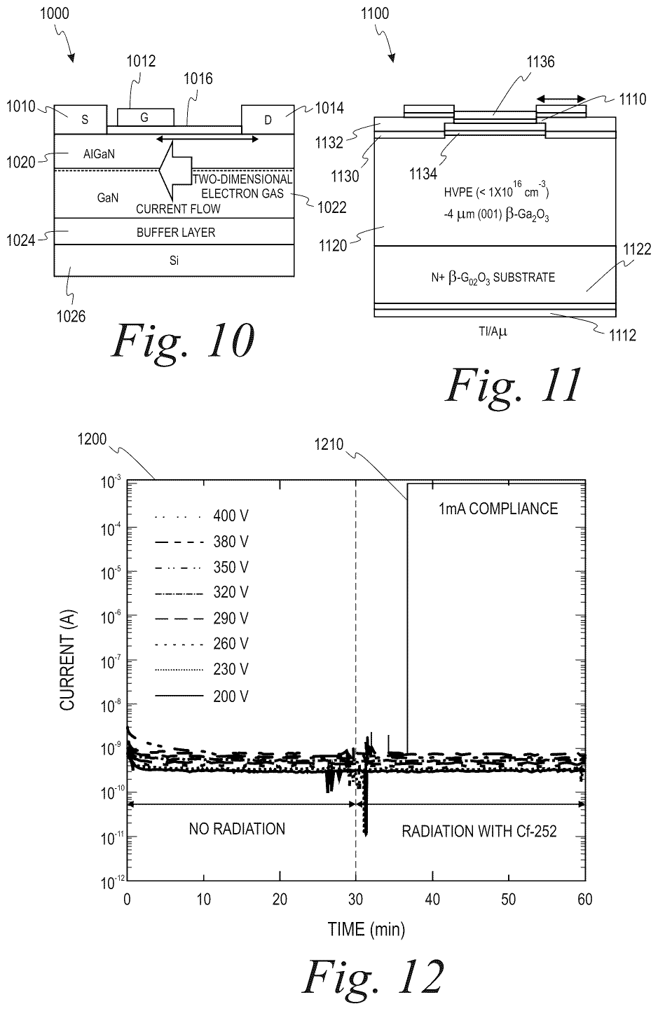

FIG. 10 shows a cross section of a GaN power device such as a high electron mobility transistor 1000. The power device 1000 includes a source contact 1010, a gate contact 1012, and a drain contact 1014 arranged laterally on a gate insulator 1016. The source 1010, gate 1012, and drain 1014 are fabricated from a conductive metal material. The gate insulator 1016, source contact 1010, and drain contact 1014 rest on an AlGaN layer 1020. The source, drain and gate are created in the AlGaN layer 1020 under the respective contacts 1010, 1014 and 1016. The GaN power device 1000 has a lateral current flow through a body layer 1022 that is GaN with a level of doping. The body layer 1022 is fabricated on a buffer layer 1024. The buffer layer 1024 rests on a silicon substrate 1026. The buffer layer 1024 is composed of GaN layers whose purpose is to provide stress relief between a Si substrate 1026 and the surface GaN layer 1022. A two dimensional electron gas flows through the body layer 1022 to generate current flow. The two dimensional electron gas exists due to the body layer 1022. The body layer 1022 is the region where current flows from drain to source. A single event voltage breakdown may be set by adjusting the doping level of the GaN body layer 1022, the dimensions of the GaN body layer 1022, the construction of the overlying metal between source and drain, and other structural parameters that could lower the peak electric field, and hence minimize the energy storage in the structure, at a given drain voltage.

FIG. 11 shows a cross section of a Ga₂O₃ diode 1100. The diode 1100 includes a cathode 1110, and an anode 1112. The cathode 1110 rests on an epitaxial layer 1120 and a substrate 1120. In this example, the anode 1112 is titanium/gold alloy. In this example, a layer of aluminum oxide 1130 is formed on the epitaxial layer 1120. A layer of titanium oxide 1132 is formed on the layer 1130. An aperture is formed through the layer 1130. A first layer 1134 of platinum and platinum oxide is formed in contact with the epitaxial layer 1120 to define the cathode. A second layer 1136 of platinum and platinum oxide is formed on the first layer 1134 to provide an electrical contact for the cathode 1110. The substrate 1122 is n doped Ga₂O₃ and the epitaxial layer 1120 is Ga₂O₃. A single event voltage breakdown may be set by adjusting the doping level of the epitaxial layer 1120, the dimensions of the layer 1120, and other structural parameters.

FIG. 12 is a graph 1200 showing the current flow through the example diode 1100 in FIG. 11 and time that different voltages were applied in testing. In the testing, radiation with Cf-252 was applied to the example diode 1100. Various plots of different voltages are shown. As shown by the plots in the graph 1200, voltages below 400V were insufficient to cause a single event breakdown. However, the single event breakdown voltage is shown as a plot 1210 that occurred at 400 V after exposure to the Cf-252 radiation. Thus, the graph 1200 shows that the principles herein may be applied for Ga₂O₃ based devices that may be designed for higher single event breakdown voltages.

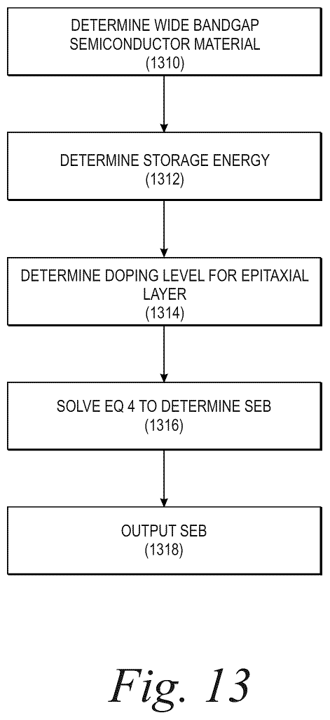

Another application is determining the single event breakdown voltage for a wide bandgap semiconductor power device. The technique would use the known doping concentration used to fabricate the device. Equation 4 could then be used to determine the actual single event breakdown voltage for the already manufactured device. FIG. 13 is a flow diagram of an example method to determine the single event breakdown voltage of a wide bandgap semiconductor power device. The type of wide bandgap semiconductor material is determined for the power device (1310). A storage energy corresponding to the critical energy density of the wide bandgap semiconductor material is input (1312). The doping level of the epitaxial layer is determined from the device specification or processing parameters, or through calculations from the rated breakdown voltage (1314). Thus, Equation 5 may be applied to determine the doping level from a desired rated breakdown voltage. Equation 4 may be applied to solve for the single event breakdown voltage with the input of the stored energy and doping level (1316). The resulting single event breakdown voltage is output (1318).

A portion of the disclosure of this patent document contains material which is subject to copyright protection. The copyright owner has no objection to the facsimile reproduction by anyone of the patent document or the patent disclosure, as it appears in Patent Office patent files or records, but otherwise reserves all copyright rights whatsoever.

Unless the context clearly dictates otherwise and where a range of values is provided, it is understood that each intervening value, to the tenth of the unit of the lower limit, between the upper and lower limit of that range, and any other stated or intervening value in that stated range is encompassed within the technology. The upper and lower limits of these intervening ranges, which may be independently included in the intervening ranges, are also encompassed within the technology, subject to any specifically excluded limit in the stated range. Where the stated range includes one or both of the limits, ranges excluding either or both of those included limits are also included in the technology.

Furthermore, where a value or values are stated herein as being implemented as part of the technology, it is understood that such values may be approximated, unless otherwise stated, and such values may be utilized to any suitable significant digit to the extent that a practical technical implementation may permit or require it.

Unless defined otherwise, all technical and scientific terms used herein have the same meaning as commonly understood by one of ordinary skill in the art to which this technology belongs. Although any methods and materials similar or equivalent to those described herein can also be used in the practice or testing of the present technology, a limited number of the exemplary methods and materials are described herein.

When a particular material is identified as being used to construct a component, obvious alternative materials with similar properties may be used as a substitute. Furthermore, unless specified to the contrary, any and all components herein described are understood to be capable of being manufactured and, as such, may be manufactured together or separately.

It must be noted that as used herein and in the appended claims, the singular forms “a,” “an,” and “the” include their plural equivalents, unless the context clearly dictates otherwise.

All publications mentioned herein are incorporated herein by reference in their entirety to disclose and describe the methods and/or materials which are the subject of those publications. The publications discussed herein are provided solely for their disclosure prior to the filing date of the present application. Nothing herein is to be construed as an admission that the present technology is not entitled to antedate such publication by virtue of prior invention. Further, the dates of publication provided may be different from the actual publication dates, which may need to be independently confirmed.

The subject headings used in the detailed description are included only for the ease of reference of the reader and should not be used to limit the subject matter found throughout the disclosure or the claims. The subject headings should not be used in construing the scope of the claims or the claim limitations.

Although the technology herein has been described with reference to particular examples, it is to be understood that these examples are merely illustrative of the principles and applications of the technology. In some instances, the terminology and symbols may imply specific details that are not required to practice the technology. For example, although the terms “first” and “second” may be used, unless otherwise specified, they are not intended to indicate any order but may be utilized to distinguish between distinct elements. Furthermore, although process steps in the methodologies may be described or illustrated in an order, such an ordering is not required. Those skilled in the art will recognize that such ordering may be modified and/or aspects thereof may be conducted concurrently or even synchronously.

It is therefore to be understood that numerous modifications may be made to the illustrative examples and that other arrangements may be devised without departing from the spirit and scope of the technology.

1. A device for conducting current, comprising:
an epitaxial layer composed of a wide bandgap semiconductor material having a critical energy density with a specific doping level, the specific doping level determined to provide a specific single event breakdown voltage corresponding to the critical energy density for the device; and
a drain layer in contact with the epitaxial layer.

2. The device of claim 1, wherein the wide bandgap semiconductor material is silicon carbide (SiC).

3. The device of claim 1, wherein the wide bandgap semiconductor material is gallium nitride (GaN), gallium oxide (Ga₂O₃), aluminum nitride (AlN), cubic boron-nitride (c-BN), or diamond.

4. The device of claim 1, wherein the device is a diode, wherein the drain layer is the cathode and an anode is defined in the epitaxial layer.

5. The device of claim 1, wherein the device is a field effect transistor, the device further comprising:
a source contact;
a gate; and
a source in proximity to the gate and coupled to the source contact, the source coupled to the epitaxial layer, wherein current flow between the source and the drain is controlled by a gate voltage.

6. The device of claim 2, wherein the doping level is between approximately 1e14 cm⁻³ to 5e16 cm⁻³ corresponding to a single event breakdown voltage between approximately 2400 and 300 volts.

7. The device of claim 1, wherein a maximum thickness of the epitaxial layer is selected based on a thickness of a depletion region in the epitaxial layer at the single event breakdown voltage.

8. The device of claim 1, wherein the doping level, N_{EPI}, is determined by solving the equation:
$${V}_{SEB , sat} = {( \frac{2 * {U}_{SEB , sat}}{\sqrt{2 q {ε}_{o} {ε}_{SiC}}} )}^{\frac{2}{3}} {N}_{EPI}^{- \frac{1}{3}}$$
where U_{SEB,sat} is a critical energy stored in the epitaxial layer when single event voltage breakdown occurs, V_{SEB,sat} is the single event breakdown voltage, q is a magnitude of electronic charge, so is a permittivity of free space, and ε_{SiC} is a relative permittivity of the wide bandgap semiconductor.

9. A method of fabricating a wide bandgap semiconductor power device having a single event breakdown voltage, the method comprising:
determining a critical energy density value of a wide bandgap semiconductor material;
determining a doping level for an epitaxial layer for a desired single event breakdown voltage corresponding to the critical energy density;
doping a substrate to form a drain layer;
growing an epitaxial layer of the wide bandgap semiconductor material on the drain layer; and
doping the wide bandgap semiconductor material at the determined doping level.

10. The method of claim 9, wherein the wide bandgap semiconductor material is silicon carbide (SiC).

11. The method of claim 9, wherein the wide bandgap semiconductor material is gallium nitride (GaN), gallium oxide (Ga₂O₃), aluminum nitride (AlN), cubic boron-nitride (c-BN), or diamond.

12. The method of claim 9, wherein the device is a diode, wherein the drain layer is the cathode and an anode is defined in the epitaxial layer.

13. The method of claim 9, wherein the device is a field effect transistor, and wherein the method further comprises:
growing a source contact on the epitaxial layer opposite the drain layer;
doping two source regions under the source contact in the epitaxial layer; and
growing a gate between the source regions.

14. The method of claim 10, wherein the doping level is approximately between 1e14 cm 3 to 5e16 cm⁻³ corresponding to a single event breakdown voltage approximately between 2400 and 300 volts.

15. The method of claim 9, wherein a maximum thickness of the epitaxial layer is selected based on a thickness of a depletion region in the epitaxial layer at the single event breakdown voltage.

16. The method of claim 9, wherein the doping level, N_{EPI}, is determined by solving the equation:
$${V}_{SEB , sat} = {( \frac{2 * {U}_{SEB , sat}}{\sqrt{2 q {ε}_{o} {ε}_{SiC}}} )}^{\frac{2}{3}} {N}_{EPI}^{- \frac{1}{3}}$$
where U_{SEB,sat} is a critical energy stored in the epitaxial layer when the single event breakdown voltage occurs, V_{SEB,sat} is the single event breakdown voltage, q is a magnitude of electronic charge, ε₀ is a permittivity of free space, and ε_{SiC} is a relative permittivity of the wide bandgap semiconductor.

17. A method to determine a single event breakdown voltage for a power device including an epitaxial layer composed of a wide bandgap semiconductor material coupled to a drain, the method comprising:
determining a critical energy density value of the wide bandgap semiconductor material;
determining a doping level of the epitaxial layer; and
determining the single event breakdown voltage of the power device based on the doping level of the epitaxial layer.

18. The method of claim 17, wherein the single event breakdown voltage (V_{SEB,sat}) IS determined via:
$${V}_{SEB , sat} = {( \frac{2 * {U}_{SEB , sat}}{\sqrt{2 q {ε}_{o} {ε}_{SiC}}} )}^{\frac{2}{3}} {N}_{EPI}^{- \frac{1}{3}}$$
where U_{SEB,sat} is a critical energy stored in a critical energy stored in the epitaxial layer when the single event breakdown voltage occurs, q is the magnitude of electronic charge, ε₀ is the permittivity of free space, ε_{SiC} is the relative permittivity of the wide bandgap semiconductor, and N_{EPI} is the doping level.

19. The method of claim 17, wherein the device is one of a diode or a transistor.

20. The method of claim 17, wherein the wide bandgap semiconductor material is silicon carbide (SiC).
